(19) United States
(12) Patent Application Publication
(10) Pub. No.: US 2010/0136794 A1
(43) Pub. Date: Jun. 3, 2010

(54) METHOD FOR REMOVING ETCHING RESIDUES FROM SEMICONDUCTOR COMPONENTS

(75) Inventors: Berthold Ferstl, Bensheim (DE); Andreas Kuehner, Darmstadt (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, Ludwigshafen (DE)

(21) Appl. No.: 12/598,443

(22) PCT Filed: May 9, 2008
(86) PCT No.: PCT/EP2008/055738

§ 371 Date: Nov. 2, 2009

(30) Foreign Application Priority Data
May 14, 2007 (EP) 07108147.5

(51) Int. Cl. H01L 21/306

(52) U.S. Cl. 438/745; 257/E21.219

(57) ABSTRACT

A method for cleaning structured surfaces of semiconductor components to remove photoresist and etching residues after the etching of the surface, comprising: a) treatment of the surface with an acidic aqueous solution comprising one or more acids and one or more oxidizing agents, b) removal of the photoresist and c) washing with demineralized water in the stated sequence.

The present invention relates to methods for cleaning structured surfaces of semiconductor components to remove photoresist and etching residues after the etching of the surface.

Back-end-of-line (BEOL) metallization (conductor tracks) on semiconductor components substantially comprise an aluminum layer applied by sputtering and having an optional proportion of up to 5% of copper and/or silicon. The conductor tracks are produced photolithographically. An SiO₂ layer between the individual metal layers, which are connected perpendicularly by Via studs (tungsten or aluminum) serves as a dielectric. The structures (conductor tracks and Via studs) are produced by plasma etching. The conductor tracks are usually produced by the following process steps:
1. Full-area sputtering of the following layers onto an SiO₂ insulation layer:
   a) thin Ti/TiN layer as a diffusion barrier,
   b) AlCu metallization layer and
   c) thin Ti/TiN layer as an antireflective coating (ARC);
2. application of the positive photoresist by spin coating with subsequent exposure and development of the structures;
3. etching of the layers by plasma etching with the use of halogen-containing etching gases;
4. removal of the photoresist;
5. removal of the etching residues (Post Etch Residues, PER) by means of a wet process;
6. washing with water (spray process).

The structuring of SiO₂ layers takes place in a similar manner, an SiO₂ layer being structured in step 1 instead of the Al(Si/Cu) layer.

Etching residues, the so-called Post Etch Residues, PER), form during step 3, to a particularly pronounced extent on the side walls of the aluminum conductor tracks. These, like the remaining photoresist, have to be removed completely before the further processing during steps 4 and 6.

The removal of the photoresist is effected in particular with the aid of dry methods, for example using an oxygen or H₂O plasma. However, the treatment with a plasma is not capable of completely removing from the surface the residues procured during the preceding plasma etching step. These etching residues, frequently also referred to as post etch residues (PER), therefore have to be removed by an additional wet chemical treatment.

Organic solutions which comprise complexing agents and water can be used here. The most frequently used products at present are amine-containing organic solvent mixtures which may optionally comprise corrosion inhibitors, complexing agents and surfactants. In addition, for example, WO 2005/098920 discloses an acidic aqueous solution comprising an organic acid and an oxidizing agent.

What is disadvantageous about the cleaning methods described is that stubborn etching residues are removed from the surface only to an insufficient extent under unfavorable conditions, in particular in the case of overetching or in the case of aging of the residues during storage.

It is an object of the present invention, compared with the abovementioned prior art, to provide a method of the type mentioned at the outset by means of which even stubborn etching residues can be reliably removed without attacking the structures of the semiconductor component.

The present invention is based on the discovery that a wet chemical treatment with an acidic aqueous solution before the removal of the photoresist exhibits a considerably improved cleaning effect.

The present invention therefore relates to a method for cleaning structured surfaces of semiconductor components to remove photoresist and etching residues after the etching of the surface, comprising:
a) treatment of the surface with an acidic aqueous solution comprising one or more acids and one or more oxidizing agents,
b) removal of the photoresist and
c) washing with demineralized water
   in the stated sequence.

Surprisingly, it is possible, by means of a wet chemical treatment with an acidic aqueous solution before the plasma treatment, to achieve substantially improved cleaning results compared with the reverse sequence customary to date. Surprisingly, the etchings residues (PER) can be removed substantially more reliably and completely during the cleaning process than is the case with the reverse cleaning sequence.

Here, neither the metallized conductor tracks nor other surfaces, such as, for example, comprising TiN or SiO₂, are noticeably attacked.

In an advantageous development of the method according to the invention, step a) can be repeated between steps b) and c).

In a further advantageous development of the method according to the invention, the acidic aqueous solution comprises an organic acid from the group consisting of the hydroxycarboxylic acids and/or the group consisting of the mono-, di- and tricarboxylic acids. The organic acid is particularly preferably selected from the group consisting of glycolic acid, lactic acid, hydroxybutyric acid, glyceric acid, malic acid, tartaric acid, citric acid, malonic acid, succinic acid, glutaric acid and maleic acid.

The oxidizing agent is preferably selected from the group consisting of hydrogen peroxide and ammonium peroxodisulfate.

It is furthermore advantageous if the acidic aqueous solution comprises at least one anionic and/or one nonionic surfactant in an amount of from 1 ppm to 1%, based on the total weight, since this promotes the wetting of the surface.

The method according to the invention can be used in particular in the production of semiconductor components. The present invention therefore furthermore relates to a method for the production of a semiconductor component comprising the cleaning method according to the invention.

The individual steps of the method according to the invention are described in detail below.

In step a), the surface is treated with an acidic aqueous solution comprising one or more acids and one or more oxidizing agents. Here, the major part of the etching residues is removed. The treatment is usually effected for from 10 seconds to 1 hour, preferably from 1 minute to 30 minutes, particularly preferably from 10 minutes to 25 minutes.

The procedure may be effected at room temperature but also preferably at elevated temperature up to about 90° C. The procedure is preferably effected at from 30° C. to 80° C., particularly preferably at from 40° C. to 75° C.

In the context of the present invention, a solution having a pH of about less than 5, preferably less than 4, particularly preferably less than 3, is acidic. In principle, all customary inorganic and/or organic acids, individually or in combination, can be used in step a). Sulfuric acid or citric acid may be mentioned by way of example here.

Preferred acidic solutions for carrying out step a) are the aqueous solutions which comprise at least one organic acid. Acids selected from the group consisting of the hydroxycarboxylic acids and/or the di- and tricarboxylic acids are particularly preferred. Suitable hydroxycarboxylic acids are glycolic acid, lactic acid, hydroxybutyric acid, glyceric acid, malic acid, tartaric acid and citric acid. Suitable dicarboxylic acids are malonic acid, succinic acid, glutaric acid and maleic acid, individually or in combination.

In addition to at least one, preferably organic, acid, at least one oxidizing agent is present in the acidic solution. In principle, all oxidizing agents which can oxidatively degrade the etching and photoresist residues without excessively attacking the semiconductor structure can be used as suitable oxidizing agents. Oxidizing agents free of metal ions, such as hydrogen peroxide and ammonium peroxodisulfate are preferred and may be present individually or in combination in the acidic solutions. Acidic solutions which comprise no HF or HF-generating compounds are furthermore preferred.

In addition, a very wide range of additives for improving the cleaning effect and for protecting the surfaces, which are not to be attacked, may be present in the acidic solutions. Thus, it has proven advantageous if corrosion inhibitors are present in the solutions. Imidazoline compounds are preferably added as corrosion inhibitors to solutions which are intended for the treatment of wafer surfaces which have, for example, metallizations comprising tungsten and aluminum. Suitable imidazoline compounds are, for example, benzimidazoles (alkyl-substituted imidazolines or 1,2-dialkylimidazolines), aminobenzimidazoles and 2-alkylbenzimidazoles. Particularly good cleaning results are obtained with solutions which comprise oleic acid hydroxyethylimidazoline as a corrosion inhibitor.

For promoting the cleaning effect and for protecting the wafer surfaces, it is advantageous if an aprotic polar solvent is added to the solution. Suitable aprotic polar solvents for this purpose are N-methylpyrrolidone (NMP), ethylene glycol, propylene glycol, dimethyl sulfoxide (DMSO) and 1-methoxy-2-propyl acetate (PGMEA). These organic solvents may be present in the solution individually or as a mixture.

Furthermore, it has proven advantageous if surface-active substances are additionally present in the cleaning solution. Anionic surfactants have proven to be suitable surface-active substances. Particularly suitable surfactants are those selected from the group consisting of the aliphatic carboxylic acids and/or from the group consisting of the alkylbenzenesulfonic acids. Suitable aliphatic carboxylic acids are, for example, heptanoic acid and octanoic acid. Inter alia, dodecylbenzenesulfonic acid can be used as the alkylbenzenesulfonic acids.

Anionic surfactants can be used together with nonionic surfactants or can be replaced by them. Nonionic surfactants which may be used are those from the group consisting of the alkyl oxyalkylates and/or of the alkylphenol oxyethylates. Alkyl oxyalkylates suitable for this purpose are, for example, fatty alcohol alkoxylates. Inter alia, octylphenol oxyethylate can be added as the alkylphenol oxyethylates. Furthermore, sorbitan compounds, such as polyoxyethylene sorbitan fatty acid esters, are suitable as surfactants in the solutions according to the invention. These include surfactants such as, for example, products obtainable commercially under the name Tween®.

The experiments carried out have shown that, at temperatures in the range from 40° C. to 70° C., the solutions according to the invention give substantially improved cleaning results compared with cleaning solutions known to date.

The acidic cleaning solutions which can be used in step a) preferably have compositions as shown in the table below:

TABLE 1

| | 1 | 2 | 3 | 4 | 5 | 6 | 7 | 8 |
|---|---|---|---|---|---|---|---|---|
| Organic acid | x | x | x | X | x | x | x | x |
| Oxidizing agent | x | x | x | X | x | x | x | x |
| Solvent | | x | | X | | | x | x |
| Surfactant | | | x | X | | x | x | |
| Corrosion inhibitor | | | | | x | x | x | x |

The acidic cleaning solutions preferably comprise the following individual components:
organic acid from the group consisting of the hydroxycarboxylic acids and/or di- and tricarboxylic acids in an amount of from 0.1 to 30%
oxidizing agent in an amount of from 0.1 to 10%
corrosion inhibitors, for example from the group consisting of the imidazoline compounds, for tungsten and aluminum in an amount of from 1 ppm to 1%
aprotic polar solvent in an amount of from 0.1 to 10%
anionic surfactant from the group consisting of the aliphatic carboxylic acids and of the alkylbenzenesulfonic acids in an amount of from 1 ppm to 1% and/or
nonionic surfactant from the group consisting of the alkyl oxyalkylates, alkylphenol oxyethylates and sorbitan compounds in an amount of from 1 ppm to 1%.

In suitable cleaning solutions having improved properties, the components may therefore preferably be present in the following amounts:

| | |
|---|---|
| di-, tri- or hydroxycarboxylic acid | from 0.1 to 30% |
| hydrogen peroxide | from 0.1 to 30% |
| corrosion inhibitor | from 1 ppm to 1% |
| anionic or nonionic surfactant | from 1 ppm to 1% |

The photoresist is then removed in step b) of the method according to the invention. This step can be carried out either with an organic stripper or by dry method, for example using an oxygen plasma. The removal of photoresist with strippers which generally comprise polar organic solvents is generally customary and known. The plasma treatment with oxygen is likewise a widely used, generally known method.

Finally, the surface of the semiconductor component is washed with demineralized water in step c), in order to remove the dissolved residues and solvent. In this case, demineralized is to be understood simply as meaning that no undesired contamination with impurities, such as, for example, heavy metal ions or particles, is caused by the water. The required purity should be appropriately established in the context of the use of the semiconductor component. Water of suitable purity is commercially available and is frequently also offered under the designation ultrapure water.

Depending on the further processing, the semiconductor component may also be dried. This can be effected, for example, in a nitrogen stream.

The method according to the invention can be used on spray units as well as in tank processors.

Advantageously, the solutions used in steps b) and c) according to the invention are stable compositions which show no decomposition even after a relatively long storage time. A not inconsiderable advantage of the compositions is their environmental compatibility, so that they can easily be disposed of. If desired, they can also be recycled.

Surprisingly, it is possible with the two-stage cleaning method according to the invention, in a comparable or shorter cleaning time (stripping time), particularly in the case of strong topography and associated overetching of regions, to achieve further improved cleaning results compared with the one-stage methods known to date. Even under unfavorable circumstances, the etching residues (PER) can be completely removed during the cleaning process, but neither the metallized conductor tracks nor other surfaces, such as, for example, comprising TiN or SiO₂, are noticeably attacked.

All documents cited are hereby incorporated by reference into the present patent applications. All stated percentages refer to the weight based on the total weight of the mixture, unless stated to the contrary.

The following examples explain the present invention without limiting it thereto.

### EXAMPLES

Tests were carried out on wafers which had etching residues which were difficult to remove, owing to overetching and aging for several days.

### Example 1

### Step a)

The etching residues were removed by treating the semiconductor component for 20 minutes at 60° C. with an acidic aqueous cleaning solution by the immersion method (the spray method gives comparable results). The acidic cleaning solution used corresponded to that which was used in Example 2 of WO 2005/098920.

### Step b)

The photoresist was removed with an organic stripper (Positive Photoresist Stripper Super X VLSI Selectipur® from BASF).

Washing was then effected at 22° C. for 2 minutes with demineralized water and drying was effected for 5 minutes with nitrogen.

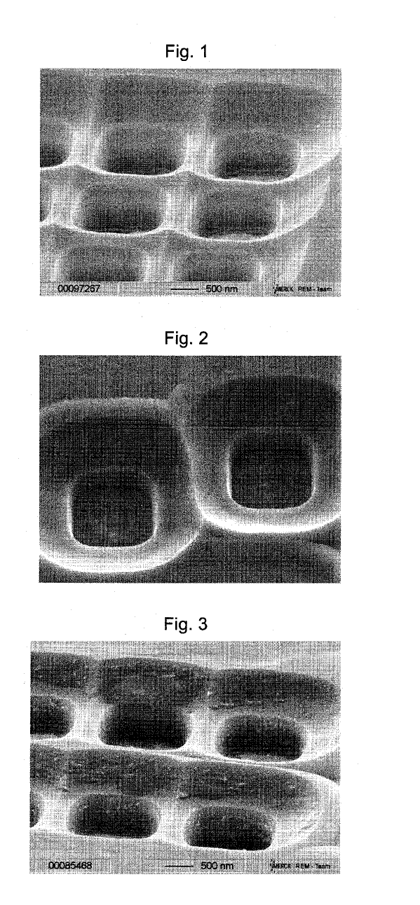

FIG. 1 shows the semiconductor component after the treatment. All etching residues were completely removed.

### Example 2

Step a) was carried out as described in Example 1.

Step b)

The photoresist was removed by treatment with an oxygen plasma.

FIG. 2 shows the semiconductor component after the treatment. All etching residues were completely removed.

### Comparative Example A

The procedure was as in Example 2, except that step b) and step a) were carried out in the reverse sequence.

FIG. 3 shows the semiconductor component after the treatment. Etching residues are still present, particularly in the Via stud regions. Under these worst case conditions, the treatment according to the prior art does not result in adequate cleaning of the surface.

1. A method for cleaning the structured surfaces of semiconductor components to remove photoresist and etching residues after the etching of the surface, comprising:
a) treating the surface with an acidic aqueous solution comprising one or more acids and one or more oxidizing agents,
b) removing the photoresist and
c) washing with demineralized water
in the stated sequence.

2. The method according to claim 1, wherein a) is repeated between b) and c).

3. The method according to claim 1, wherein an oxygen plasma or an organic stripper is used for removing the photoresist.

4. The method according to claim 1, wherein the acidic aqueous solution comprises an organic acid selected from the group consisting of the hydroxycarboxylic acids, the group consisting of the mono-, di- and tricarboxylic acids and mixtures thereof.

5. The method according to claim 4, wherein the organic acid is selected from the group consisting of glycolic acid, lactic acid, hydroxybutyric acid, glyceric acid, malic acid, tartaric acid, citric acid, malonic acid, succinic acid, glutaric acid and maleic acid.

6. The method according to claim 1, wherein the oxidizing agent is selected from the group consisting of hydrogen peroxide and ammonium peroxodisulfate.

7. The method according to claim 1, wherein the acidic aqueous solution comprises at least one anionic and/or one nonionic surfactant in an amount of from 1 ppm to 1%, based on the total weight.

8. A method for the production of a semiconductor component comprising a cleaning method according to claim 1.
